(19) United States
(12) Patent Application Publication
(10) Pub. No.: US 2021/0210478 A1
(43) Pub. Date: Jul. 8, 2021

(54) PACKAGING SOLUTIONS FOR HIGH BANDWIDTH NETWORKING APPLICATIONS

(71) Applicant: Intel Corporation, Santa Clara, CA (US)

(72) Inventors: Susheel JADHAV, Los Gatos, CA (US); Juan DOMINGUEZ, Chandler, AZ (US); Ankur AGRAWAL, Chandler, AZ (US); Kenneth BROWN, Tempe, AZ (US); Yi LI, Chandler, AZ (US); Jing CHEN, Chandler, AZ (US); Aditi MALLIK, Cupertino, CA (US); Xiaoyu HONG, Fremont, CA (US); Thomas LILJEBERG, San Jose, CA (US); Andrew C. ALDUINO, San Jose, CA (US); Ling LIAO, Fremont, CA (US); David HUI, Santa Clara, CA (US); Ren-Kang CHIOU, Palo Alto, CA (US); Harinadh POTLURI, Milpitas, CA (US); Hari MAHALINGAM, San Jose, CA (US); Lobna KAMYAB, San Jose, CA (US); Sasanka KANUPARTHI, Fremont, CA (US); Sushrutha Reddy GUJJULA, Chandler, AZ (US); Saeed FATHOLOLOUMI, Los Gatos, CA (US); Priyanka DOBRIYAL, Santa Clara, CA (US); Boping XIE, San Ramon, CA (US); Abiola AWUJOOLA, Pleasanton, CA (US); Vladimir TAMARKIN, Huntingdon Valley, PA (US); Keith MEASE, Gibbstown, NJ (US); Stephen KEELE, Allentown, PA (US); David SCHWEITZER, Collegeville, PA (US); Brent ROTHERMEL, Barto, PA (US); Ning TANG, Santa Clara, CA (US); Suresh POTHUKUCHI, Chandler, AZ (US); Srikant NEKKANTY, Chandler, AZ (US); Zhichao ZHANG, Chandler, AZ (US); Kaiyuan ZENG, Santa Clara, CA (US); Baikuan WANG, Folsom, CA (US); Donald TRAN, Phoenix, AZ (US); Ravindranath MAHAJAN, Chandler, AZ (US); Baris BICEN, Chandler, AZ (US); Grant SMITH, Bryn Athyn, PA (US)

(21) Appl. No.: 17/191,615

(22) Filed: Mar. 3, 2021

Related U.S. Application Data
(60) Provisional application No. 62/985,309, filed on Mar. 4, 2020.

(51) Int. Cl. H01L 25/18; H01L 23/473; H01R 12/71

(52) U.S. Cl. CPC H01L 25/18; H01L 2023/4087; H01R 12/716; H01L 23/473

(57) ABSTRACT

Embodiments disclosed herein include electronic packages for optical to electrical switching. In an embodiment, an electronic package comprises a first package substrate and a second package substrate attached to the first package substrate. In an embodiment, a die is attached to the second package substrate. In an embodiment, a plurality of photonic engines are attached to a first surface and a second surface of the first package substrate. In an embodiment, the plurality of photonic engines are communicatively coupled to the die through the first package substrate and the second package substrate.

This application claims the benefit of priority under 35 U.S.C. § 119(e) of U.S. Provisional Application Ser. No. US 62/985,309, filed Mar. 4, 2020, entitled “Packaging Solutions for High Bandwidth Networking Applications”, the entire contents of which is hereby incorporated by reference in its entirety for all purposes.

### TECHNICAL FIELD

Embodiments of the present disclosure relate to electronic packaging, and more particularly to packaging solutions for high bandwidth networking applications.

### BACKGROUND

As data center traffic continues to scale, it is generally accepted that next generation networks will need tight integration of networking integrated circuits (ICs) (e.g., Ethernet switch silicon dies) and high bandwidth density photonic engines. Currently, the high bandwidth density optics are packaged on the same surface of an interposer that the IC is packaged. Since the area around the perimeter of the IC is limited, future scaling by adding additional photonic engines is limited. Some architectures have proposed implementing additional photonic engines on the system board in order to increase bandwidth. However, such architectures are limited, because the distance between the IC and the photonic engine is increased. As such, there are power penalties due to losses along the interconnect between the IC and the photonic engine.

### BRIEF DESCRIPTION OF THE DRAWINGS

FIG. 1A is a perspective view illustration of an electrical system, in accordance with an embodiment.

FIG. 1B is a cross-sectional illustration of an electrical system, in accordance with an embodiment.

FIG. 2 is an exploded view of an electrical system, in accordance with an embodiment.

FIG. 3 is a cross-sectional illustration of an electrical system, in accordance with an embodiment.

FIG. 4 is a flow diagram of a process for forming an electrical system, in accordance with an embodiment.

FIGS. 5A and 5B are illustrations of an electrical system, in accordance with an embodiment.

FIG. 6A is a process flow diagram of a process for forming an electrical system, in accordance with an embodiment.

FIG. 6B is a process flow diagram of a process for forming an electrical system, in accordance with an embodiment.

FIGS. 7A and 7B are cross-sectional illustrations of a pillar interconnect, in accordance with an embodiment.

FIGS. 8A-8F are illustrations of an electrical system, in accordance with an embodiment.

FIGS. 9A-9D are cross-sectional illustrations of interconnects and electrical systems, in accordance with an embodiment.

FIGS. 10A-10E are illustrations of sockets that can be used for optical or electrical connections, in accordance with an embodiment.

FIGS. 11A-11C are cross-sectional illustrations of electrical systems, in accordance with an embodiment.

FIGS. 12A-12C are illustrations of thermal management solutions, in accordance with an embodiment.

FIG. 13 is an illustration of a thermal management solution, in accordance with an embodiment.

FIG. 14 is a schematic of a computing device built in accordance with an embodiment.

### EMBODIMENTS OF THE PRESENT DISCLOSURE

Described herein are network switching packages for high bandwidth networking applications, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, future increases in data consumption is necessitating increased bandwidth in switching architectures. Accordingly, embodiments disclosed herein comprise network switching systems with photonic engines packaged to both the top surface and bottom surface of an interposer. Utilizing both surfaces of the interposer for photonic engines, allows bandwidth density scaling to meet future needs. Additionally, since the photonic engines are stacked over each other, the distance of the interconnects from the photonic engines to the switch die is minimized. This reduces losses, and results in improvements to power consumption.

Embodiments disclosed herein are able to stack the photonic engines (i.e., above and below the interposer) by utilizing sockets with increased stand-off heights. That is, the sockets raise the Z-height of the interposer so that there is room below the interposer in order to accommodate the additional photonic engines (and the thermal and mechanical components needed for the additional photonic engines). Additionally, the sockets are arranged so that they are offset from the photonic engines in order to fully utilize the extra space provided by the increased stand-off of the sockets.

However, it is to be appreciated that embodiments are not limited to such architectures. Particularly, embodiments disclosed herein address many different engineering obstacles that may arise when implementing such high bandwidth architectures.

Embodiments disclosed herein may be suitable for various computing infrastructures. For example, the switching architectures may be suitable in server environments. That is, the switching architectures may be implemented as a switch blade or the like. In other embodiments, the switching architectures disclosed herein may be part of a disaggregated computing network. That is, a server with fixed ratios of compute and storage resources may be “disaggregated”, i.e., broken down into their constituent components (e.g., compute modules, non-volatile memory, accelerators, storage, etc.). These individual components may then be managed as “pools” (groups) of available resources. When disaggregated components are provided with scalable management APIs and a flexible interconnect scheme (e.g., using switching architectures such as those disclosed herein), they can then be managed as pools of resources, which can be configured, or “composed,” on demand into logical systems optimized for specific workloads and applications.

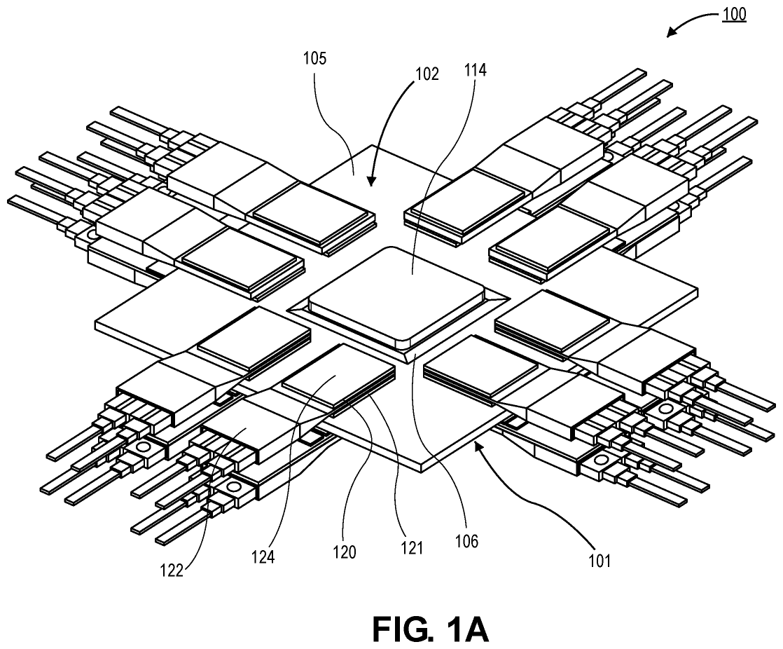

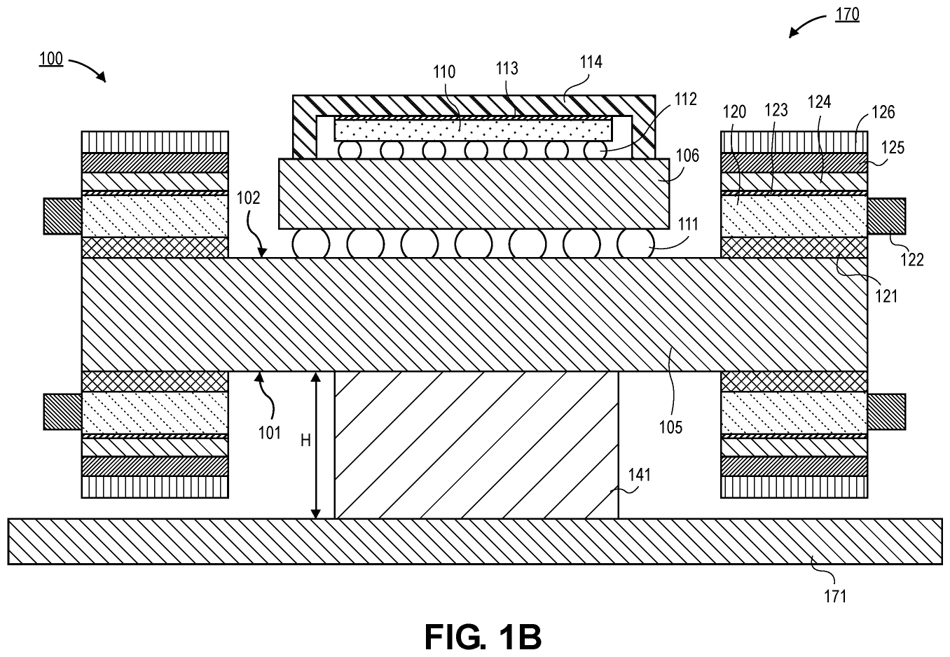

Referring now to FIG. 1A, a perspective view illustration of an electronic package 100 is shown, in accordance with an embodiment. In an embodiment, the electronic package 100 comprises a first package substrate 105. The first package substrate 105 may comprise conductive routing (e.g., traces, pads, vias, etc.) to provide electrical routing to various devices in the electronic package 100. For example, the electronic package 100 may comprise a plurality of photonic engines 120. In an embodiment, the photonic engines 120 provide the ability to convert optical signals to electrical signals or electrical signals to optical signals. For example, the photonics engines 120 may comprise one or more semiconductor photonics dies for a transmitter line and/or a receiver line. In a particular embodiment, the semiconductor photonics dies are silicon photonics dies. Optical interconnect architectures for interfacing with optical fibers may also be included on the photonics engines 120. For example, the photonics engines 120 may comprise v-grooves configured to receive optical fibers. In the illustrated embodiment, sixteen photonic engines 120 are disposed on a first package substrate 105 (i.e., eight on the first surface 101 and eight on the second surface 102). While sixteen photonic engines 120 are shown, it is to be appreciated that any number of photonic engines 120 may be disposed on the first package substrate 105. Furthermore, it is to be appreciated that disposing photonic engines 120 on the first surface 101 of the first package substrate 105 requires additional standoff height above a board (not shown). As will be described in greater detail below, the additional standoff height may be provided by a socket (or sockets) that connects the first package substrate 105 to the board.

As shown, each photonic engine 120 on the second surface 102 is stacked directly above one of the photonic engines 120 on the first surface 101. Each photonic engine 120 may include an optical input/output 122 extending away from the first package substrate 105. The optical input/output comprises optical fibers for receiving and/or transmitting optical signals. While two fibers are shown for each optical input/output 122, it is to be appreciated that a plurality of fibers may be provided to each photonic engine 120. For example, eight, sixteen, or twenty four optical fibers may be coupled to each photonic engine 120. In an embodiment, each of the photonic engines 120 is attached to the first package substrate 105 by a socket 121. In other embodiments, the photonic engines 120 may be electrically coupled to the first package substrate 105 by other interconnect architectures, such as solder bumps or the like.

In an embodiment, an IHS 124 is disposed over each of the photonic engines 120. That is, there are sixteen IHSs 124 in the electronic package 100 shown in FIG. 1. However, in other embodiments there may be fewer IHSs 124 than there are photonic engines 120. For example, a single IHS 124 may span across more than one photonic engine 120. In the illustrated embodiment, the die (not shown) is covered by a die IHS 114. The die IHS 114 may be thermally coupled to a thermal solution. For example, the thermal solution may comprise a heatsink, a fluidic cooling solution, a heat pipe, or a vapor chamber.

The die may be attached to a second package substrate 106 by any suitable interconnect, such as solder balls, copper pillars, or any first level interconnect (FLI) architecture. The die IHS 114 may land on the second package substrate 106 that is attached to the first package substrate 105. For example, the second package substrate 106 may be attached to the first package substrate 105 by solder balls, copper pillars, sockets, or any other suitable interconnect architecture. However, in other embodiments, the second package substrate 106 may be omitted, and the die may be directly attached to the first package substrate 105. The die may be attached to a first package substrate 105 by any suitable interconnect architecture, such as solder balls, copper pillars, or any FLI architecture. In an embodiment, the plurality of photonic engines 120 may surround the second package substrate 106. For example, four photonic engines 120 (i.e., two on the first surface 101 and two on the second surface 102) may be provided along each edge of the central die. The photonic engines 120 may be communicatively coupled to the central die through electrical routing in the first package substrate 105 and the second package substrate 106. In embodiments where the second package substrate 106 is omitted, the photonic engines 120 may be communicatively coupled to the central die through electrical routing in the first package substrate 105. In an embodiment, the central die below the die IHS 114 may be a switch IC. That is, the electronic package 100 may be used to provide signal switching processes. In a particular embodiment, the electronic package 100 may be a top of the rack switch.

Referring now to FIG. 1B, a cross-sectional illustration of an electronic system 170 is shown, in accordance with an embodiment. In some embodiments, the electronic system 170 may be referred to as a switch blade in a modular server system. In an embodiment, the electronic system 170 may comprise an electronic package 100 that is attached to a board 171 (e.g., a system board, motherboard, etc.). The board 171 may include a blade interface (not shown). In an embodiment, the electronic package 100 is attached to the board 171 by a socket 141. As will be described in greater detail below, the socket 141 provides an electrical connection between the electronic package 100 and the board 171 in addition to providing a vertical stand-off height H that allows for photonic engines 120 to be positioned over a first surface 101 of a first package substrate 105 of the electronic package 100.

In an embodiment, the electronic package 100 may comprise a first package substrate 105 and a second package substrate 106. The second package substrate 106 is attached to a second surface 102 of the first package substrate 105 by interconnects 111. In an embodiment, a die 110 (e.g., a switch die) is attached to the second package substrate 106 by interconnects 112. A TIM 113 may thermally couple the die 110 to an IHS 114.

In an embodiment, the electronic package 100 may comprise a plurality of photonic engines 120. A first set of photonic engines 120 may be disposed over the first surface 101 of the first package substrate 105, and a second set of photonic engines 120 may be disposed over the second surface 102 of the first package substrate 105. The photonic engines 120 may be electrically and mechanically coupled to the first package substrate 105 by sockets 121. Optical inputs/outputs 122 may extend out away from the photonic engines 120. In an embodiment, each photonic engine 120 may be thermally coupled to an IHS 124 by a TIM 123. The IHSs 124 may be in thermal contact with a heatsink 125. In an embodiment, a retention frame 126 may be disposed over each heatsink 125.

Space below the first package substrate 105 to accommodate the first set of photonic engines 120 over the first surface 101 of the first package substrate 105 is provided by the stand-off height H of the socket 141. In an embodiment, the stand-off height H may be approximately 15 mm or greater, approximately 20 mm or greater, or approximately 25 mm or greater. The stand-off height H also provides room for the additional thermal components and mechanical components over the photonic engines 120. As such, the stand-off height H is greater than a maximum thickness of the photonic engines 120.

In an embodiment, the socket 141 is positioned below the die 110. That is, the socket 141 may be within a footprint of the die 110. Positioning the socket 141 directly below the die 110 provides a shorter electrical routing path between the board 171 and the die 110. In some embodiments, the electrical routing through the socket 141 is solely for connections to the die 110. In other embodiments, electrical routing through the socket 141 may also accommodate routing for one or more of the photonic engines 120.

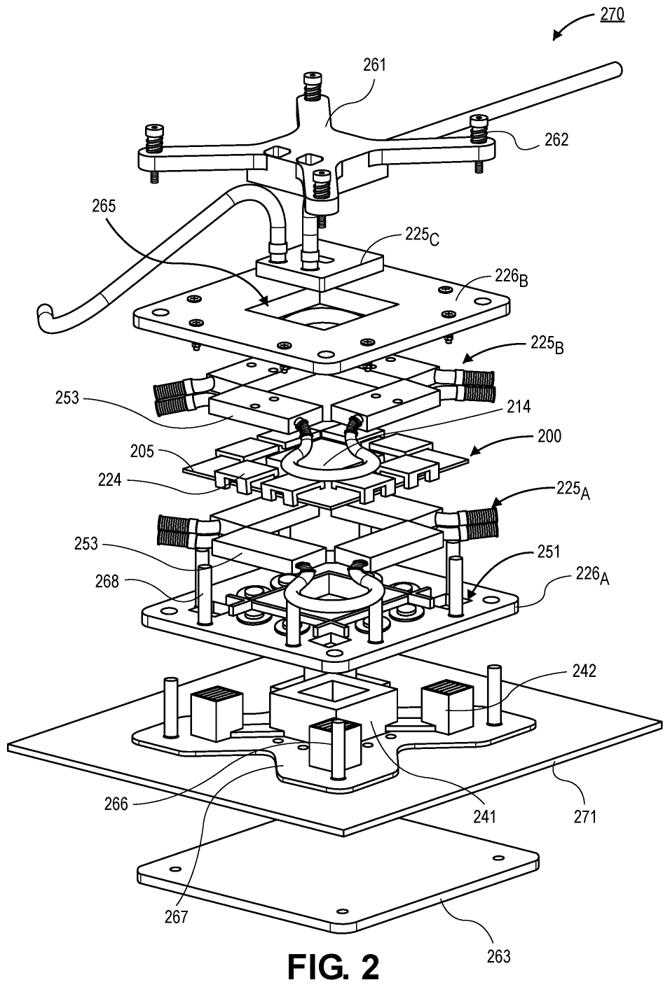

Referring now to FIG. 2, an exploded view illustration of an electronic system 270 is shown, in accordance with an embodiment. In an embodiment, the electronic system 270 may comprise a board 271. In an embodiment, a central socket 241 and peripheral sockets 242 may be attached to the board 271. In an embodiment, a first retention frame 226_{A} may be disposed over the sockets 241/242. The retention frame 242_{A} may include openings 251 to accommodate the sockets 241/242. As such, the sockets 241/242 may pass through a thickness of the first retention frame 226_{A}.

In an embodiment, a first heatsink 225_{A} is disposed over the first retention frame 226_{A}. The first heatsink 225_{A} may comprise a plurality of cooling plates 253. In some embodiments, the cooling plates 253 may be liquid cooled plates. In the illustrated embodiments, there are four cooling plates 253, with pairs of the cooling plates 253 being fluidically coupled together. In other embodiments, all of the cooling plates may be fluidically coupled together, or each of the cooling plates may have their own fluid inputs/outputs. The first heatsink 225_{A} may be used to cool the photonic engines (below IHSs 224) provided on a bottom surface of the first package substrate 205.

In an embodiment, an electronic package 200 is disposed over the first heatsink 225_{A}. The electronic package 200 may be similar to the electronic packages described above. For example, the electronic package 200 may comprise a first package substrate 205 with a first set of photonic engines over a top surface of the first package substrate 205 and a second set of photonic engines over a bottom surface of the first package substrate 205. In FIG. 2, the photonic engines are hidden by the IHSs 224 positioned over the photonic engines above and below the first package substrate 205. A die (hidden by IHS 214) may be attached to a second package substrate (not visible), with the second package substrate being attached to the top surface of the first package substrate 205. The IHSs 214 are thermally coupled to the first heatsink 225_{A} below the electronic package 200 and a second heatsink 225_{B} above the electronic package 200. In an embodiment, the second heatsink 225_{B} may be substantially similar to the first heatsink 225_{A}.

In an embodiment, a second retention frame 226_{B} is positioned over the second heatsink 225_{B}. The second retention frame 226_{B} may comprise an opening 265. The opening 265 may be aligned with the die (below IHS 214). The opening allows for a third heatsink 225_{C} to pass through the second retention frame 226_{B} and interface with an IHS 214 over the die. In an embodiment, the third heatsink 225_{C} may also be liquid cooled.

In an embodiment, a loading mechanism 261 may be disposed above the second retention frame 226_{B} and the third heatsink 225_{C}. The third heatsink 225_{C} is thermally coupled to the IHS 214. The loading mechanism 261 may include fasteners 262 (e.g., screws) that interface with pins 266 that extend up from a plate 267 attached to the sockets 241/242. The pins 266 may extend through holes in the first retention frame 226_{A} and the second retention frame 226_{B} in order to mechanically secure all of the components of the electronic system 270 together. In some embodiments, alignment pins 268 extending up from the first retention frame 226_{A} may pass through holes in the second retention frame 226_{B} in order to properly align the first retention frame 226_{A} to the second retention frame 226_{B}. In some embodiments, a back plate 263 may be disposed on the bottom surface of the board 271. Embodiments that include a back plate 263 may have the pins 266 attached to the back plate 263, and the pins 266 may extend up through the board 271 and through the plate 267.

Silicon photonics solutions for next generation applications require very short signal distances between the laser (or Tx) die and the other components. Ideally this connection would be face-to-face. However given the component complexity in the next generation silicon photonics, the short signal may need to be accomplished by using advanced package architectures. Previous solutions did not allow for complex package integration (i.e., more than 3 dies). In addition, previous solution uses a large PCB real estate which is not feasible for future integration in switch die architectures.

Accordingly, embodiments disclosed herein include short signal enablement between TIA and Tx die by embedding a die in the substrate. Additionally, such architectures are enabled through the use of a bottom assembly that incorporates a fan out on the substrate. Embodiments may also include a double sided assembly in addition to the use of a substrate cavity.

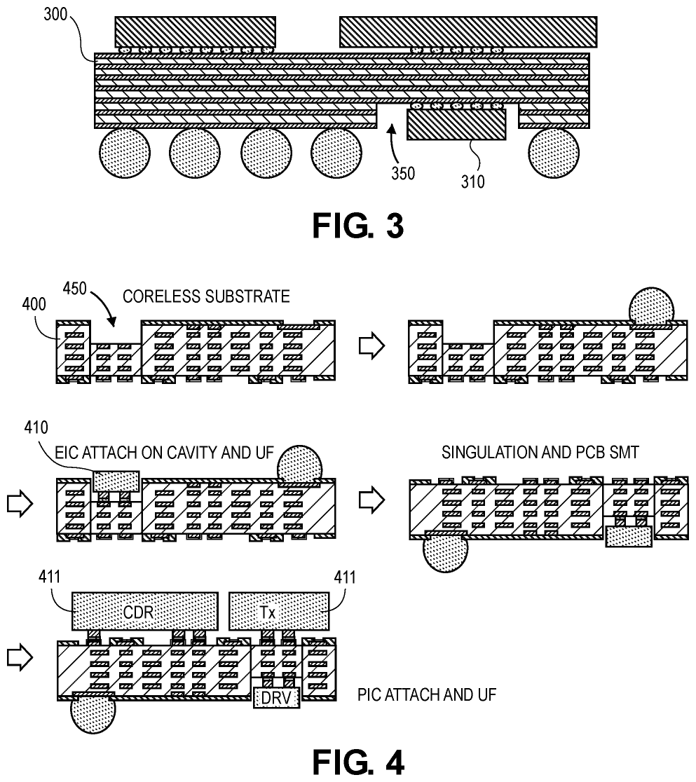

Referring now to FIG. 3, a cross-sectional illustration of a first embodiment is shown. In an embodiment, a substrate 300 with a cavity 350 is used to place the TIA or CDR die 310 on the cored or coreless substrate 300 with direct contact to photonic IC signal pads. The substrate can have stacked vias or copper planes to enable connection. In this case multiple cavities may optionally be fabricated to enable more than one die in contact with photonic IC.

A further embodiment includes the process flow (shown in FIG. 4) where the substrate 400 with the die 410 in cavity 450 is attached to the PCB and then the top dies 411 are attached. Attaching the substrate 400 to the PCB before attaching the top dies 411 reduces the risk of warpage from having a substrate with a cavity.

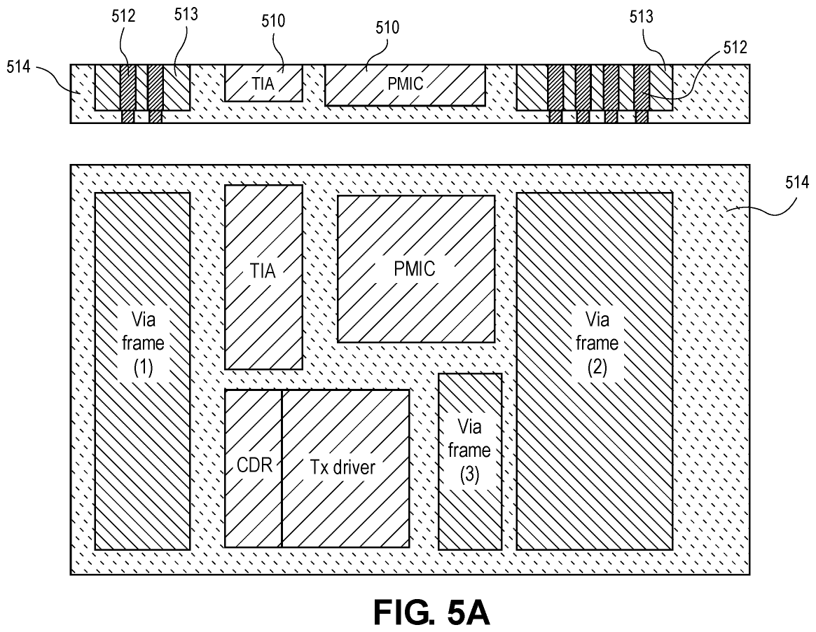

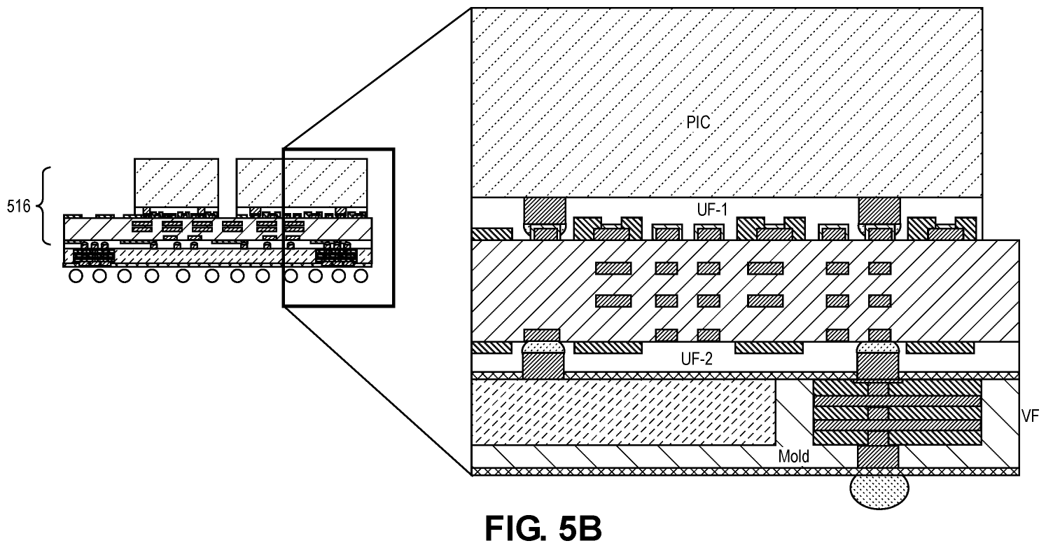

In another embodiment, the bottom dies may be embedded in a fan out solution. FIG. 5A illustrates such an embodiment. The fan out solution has direct top to bottom contacts 512 through a mold layer 514 using an embedded PCB 513. In other embodiments, the PCB 513 can be replaced by through mold vias, Cu posts or other interconnects. After the die 510 are embedded and connected using bumps or RDL (not shown), the fan out package would be singulated and placed on the bottom side of the photonic package 516 as shown in FIG. 5B. This also allows for separate risk and testing of the electrical IC compared to photonic IC.

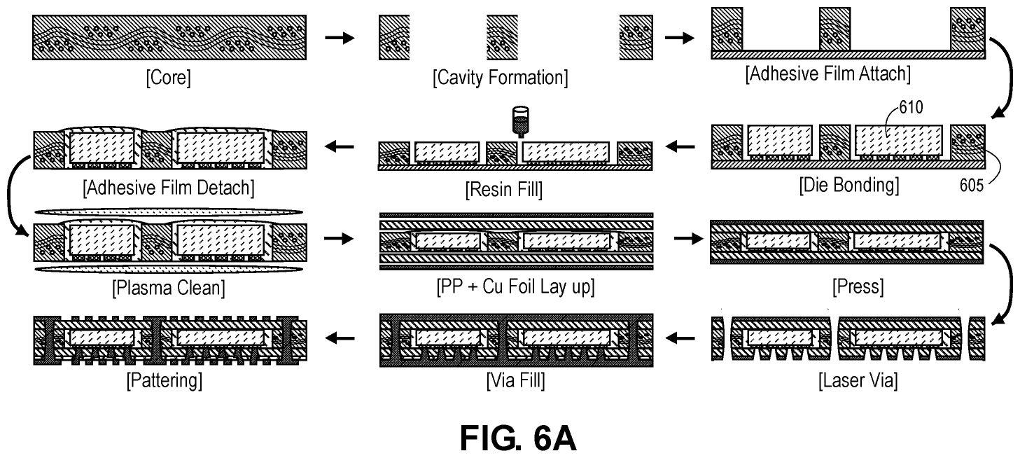

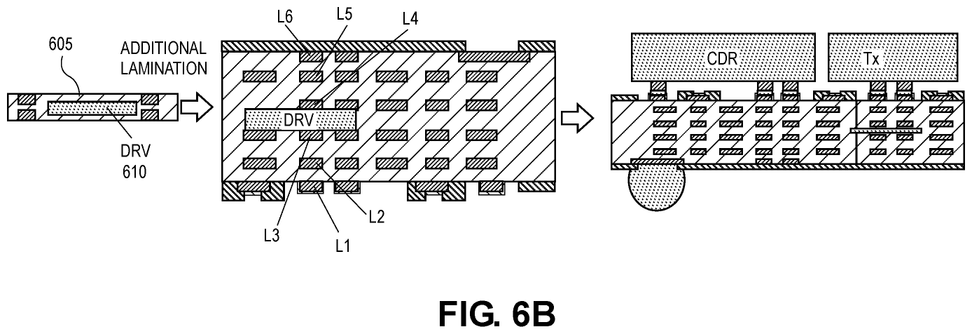

FIGS. 6A and 6B show an additional embodiment. FIG. 6A illustrates a process flow for embedding the electrical IC die 610 into the substrate 605. As shown in FIG. 6B, the substrate 605 is then assembled with the photonic ICs and other components as needed. This solution could potentially also combine any of the other two previous embodiments (i.e., substrate cavity and/or fan out integration on package bottom side).

With respect to interconnect architectures (e.g., sockets) in a system such as those described above a future product family that requires tall connectors (e.g., 20 mm or more) are used. The connector must carry very high current (e.g., approximately 2,000 A) and high speed signal at the same time. This new connector also requires very high contact density in order to fit under a chip package. Many large and bulky connectors are available on market today. However, they require press-fit assembly. The problem with the press-fit design is that it requires a relatively large pin and through hole size (0.6 minimum). This limits the pitch scalability. Additionally, the connector requires a thick motherboard, and limits signal routing to only on the bottom layer due to stub length effect created by the pin. As such, the press-fit design limits the pitch and results in an architecture that is too large to fit in the volumetric boundary. Additionally, the press-fit design cannot meet the high speed requirement.

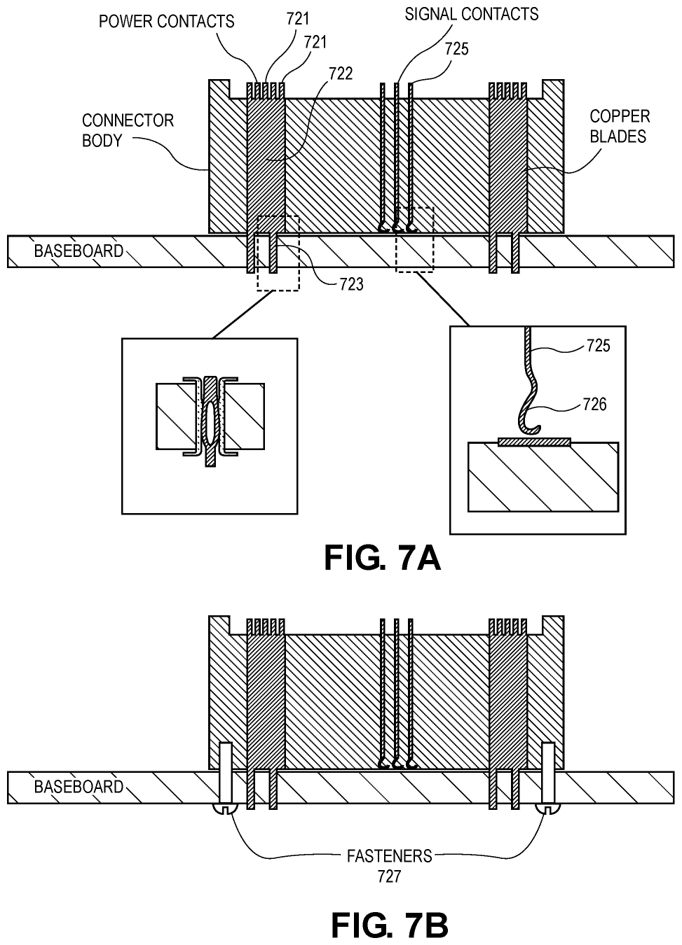

Accordingly, embodiments disclosed herein include a hybrid architecture, as shown in FIGS. 7A and 7B. A first part of the interconnect includes combining multiple power contacts 721 of same voltage polarity in a row to form a tall and thick copper which is named “Copper Blade”. Each blade 722 will have one or more press-fit pins 723. With this architecture, the number of press-fit pins and holes is reduced by 4-10×. Reducing the number of pins and holes, not only saves manufacturing cost, but also minimize the loss of copper in the motherboard which is critical for power delivery.

For signal contacts 725, instead of using a traditional press-fit pin or a solder joint, mechanical spring type contacts are used. Each spring 726 would mate with a pad on the mother board, so it does not have the stub-length problem associated with pin type connections. The spring force would be activated when the connector is being installed on the motherboard, and the friction generated by the press-fit power pins 723 would be enough to maintain the spring force. Additional compression force may be applied by the heatsink or thermal solution that would further maintain the compression throughout the life of the product.

In applications where there are more signal contacts 725 and fewer press-fit power pins 723, additional fasteners 727 can be used to ensure there is enough retention force for the spring contacts 726, as shown in FIG. 7B.

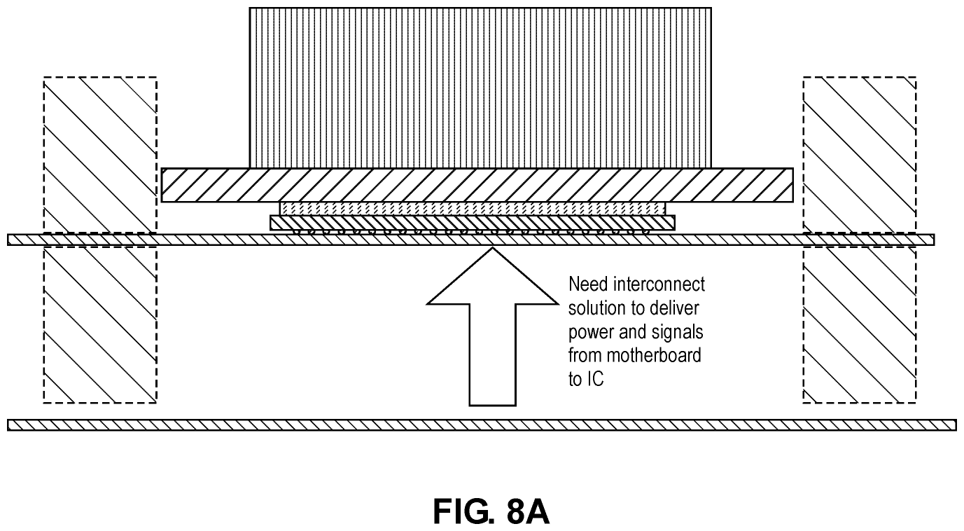

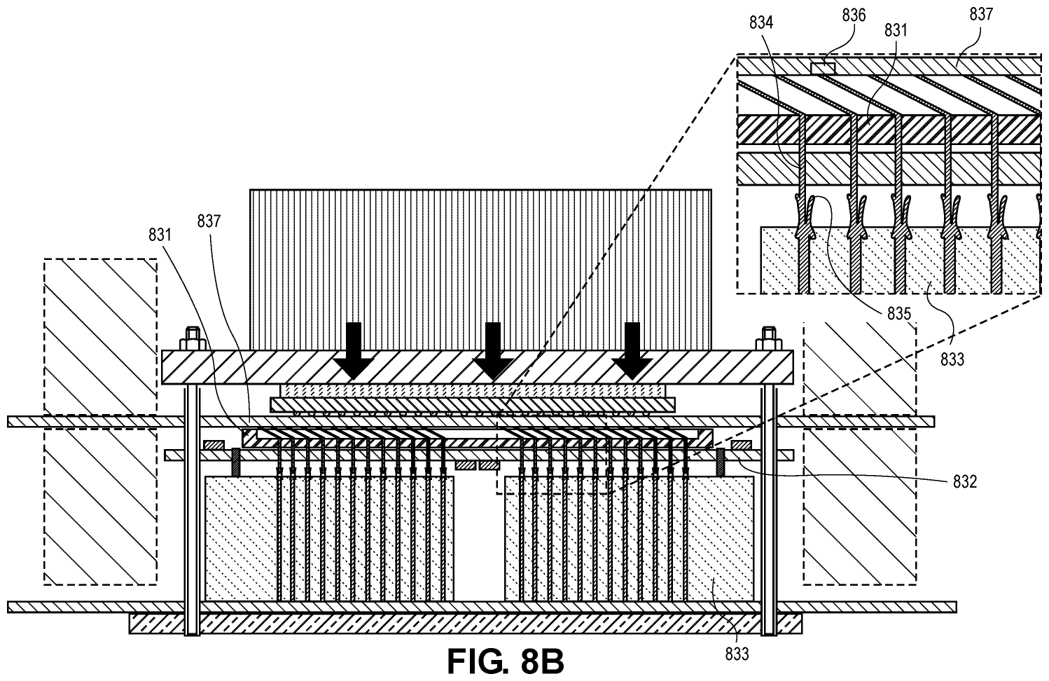

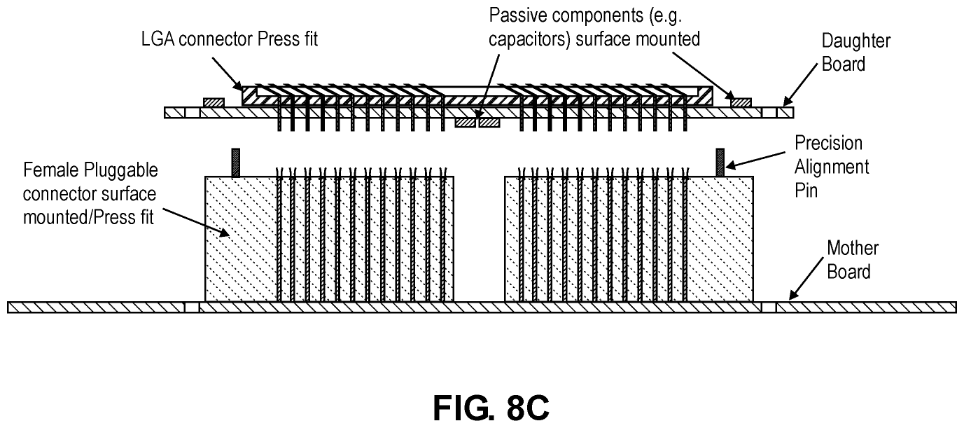

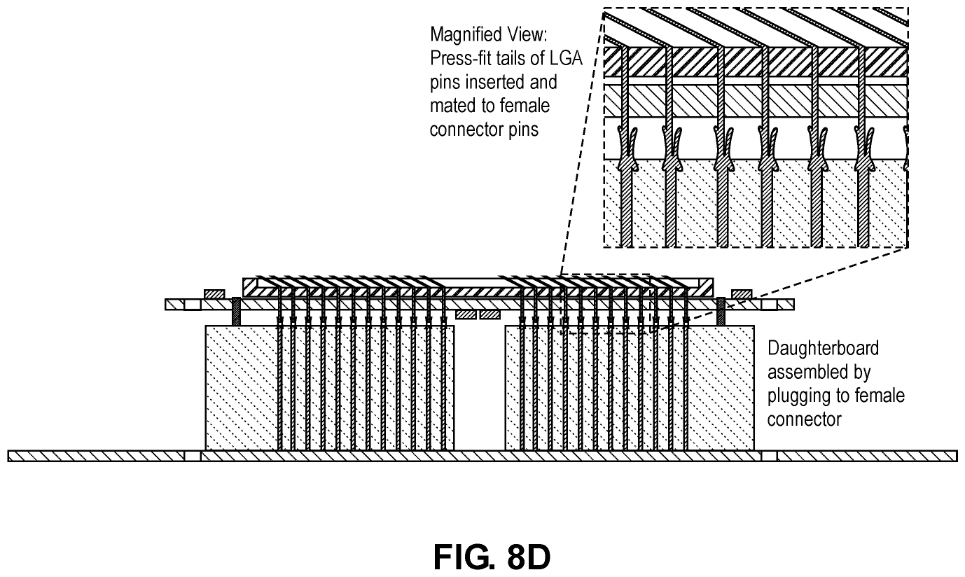

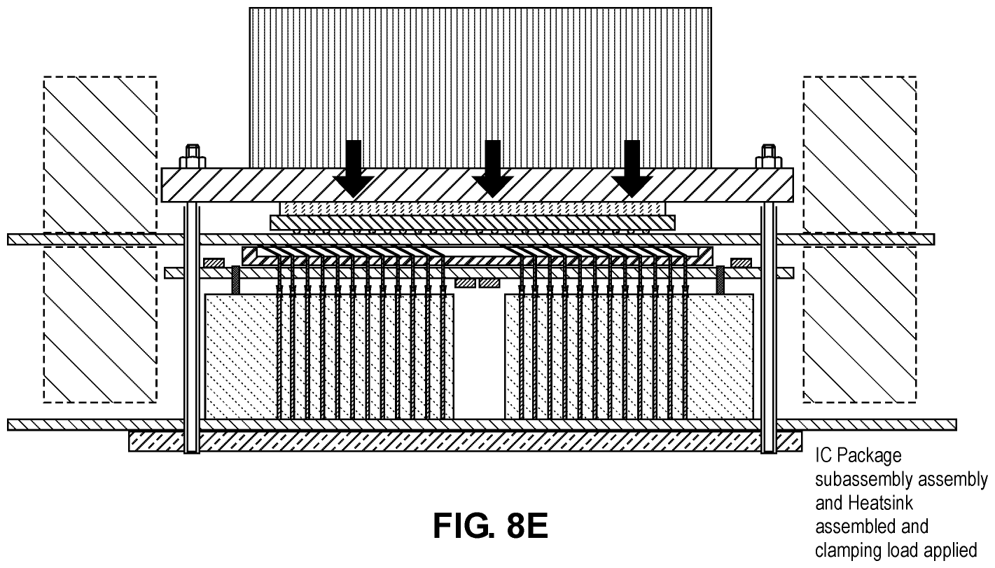

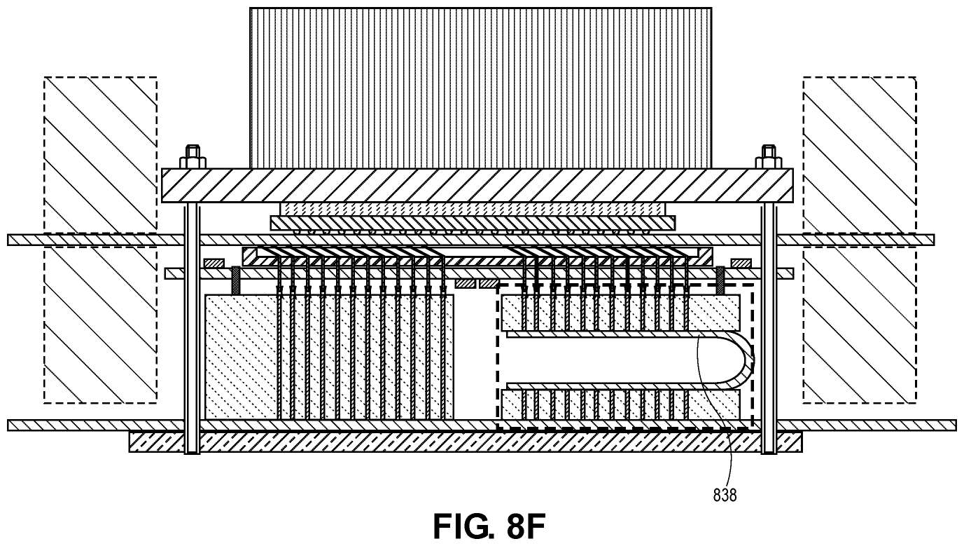

With increase in total compute performance and bandwidth, new architectures are being defined where modules such as memory and networking ports are being assembled to both top and bottom side of the IC package substrate. For example the electronic package 100 in FIG. 1A is one such architecture. An additional example is shown in FIG. 8A. Such IC packages include CPU/FPGA/Switch packages. These “dual sided” architectures provide higher compute density and also smaller footprint which means smaller electrical routing length from IC packages to modules as compared to an architecture where modules are assembled on only one side of the IC package substrate.

However, dual sided architecture needs a tall interconnect solution to supply power and transmit signals from the motherboard to the IC package. Such tall interconnect solutions need to meet several design requirements. They need to provide separable interfaces between IC package substrate and motherboard to allow system serviceability and re-workability, as needed. Additionally, they may not surface mount any part of the interconnect directly to the IC substrate to ensure robust package assembly and yield. Furthermore, such packages may provide effective and efficient power and signal delivery from mother board to IC package.

Accordingly, embodiments disclosed herein may comprise a land grid array (LGA) connector 831, a daughter board 832 and an additional receptacle type mating connector 833 which is assembled to motherboard as shown in FIG. 8B. The LGA connector 831 has contacts which has press fit (or through hole) tails 834 and which is press fit (or through hole mounted) to daughter board 832 such that the press fit (or through hole mount) tails of the connector stick through the daughter board. These press fit tails 834 of the LGA 831 are then received by the receptacle connector 833 contacts 835 and the top of the LGA 831 contacts interface with LGA pads 836 on the IC package substrate 837. As such, the electrical connection with appropriate clamping load is provided. The magnified view illustrates press fit/through hole mount tails 834 of the LGA contacts mating with a receptacle connector 835.

The proposed stackable solution avoids any part of the connector or any pins to be reflow surface mounted directly to IC package substrate which makes the IC package assembly less complex and also avoids impact to manufacturing yield compared to solutions which involve reflow surface mounting of connector components to IC package substrate. An LGA interface also makes it easier for serviceability and re-workability of connectors. The daughter board enables assembly of additional passive components such as capacitors to improve power delivery. Such daughter board solutions can also be extended to use of other module connectors such us by using flexible printed circuits and separate connectors/contact designs for power and high speed signals offering greater flexibility and configuration options to customers to design motherboards without changing IC packages.

FIGS. 8C-8E show a connector and assembly proposal which uses a LGA design that includes press fit/through hole mount style contacts (instead of surface mount). The press fit/through hole tails of the LGA contacts mate to compatible contacts of a receptacle connector. Precision dowel pin approach can be used, as shown in FIG. 8C, to ensure proper alignment of LGA contacts to the receptacle contacts. This approach eliminates solder attaching pins or a connector to IC package and therefore simplifies IC package assembly. Further, passive components such as capacitors can be assembled to the daughter board to improve power delivery performance. LGA sockets/connectors and receptacle connectors are proven solutions in the industry and, therefore, the proposed invention is viable. However, the novelty of the invention lies in the stackable method of LGA and receptacle connectors facilitated through a daughter board.

Proposed daughter board solutions can also be extended to the use of other module connectors such us by using flexible printed circuits 838 and separate connectors for power and high speed signals as shown in FIG. 8F. This offers greater flexibility and configuration options to customers to design motherboards without changing IC packages.

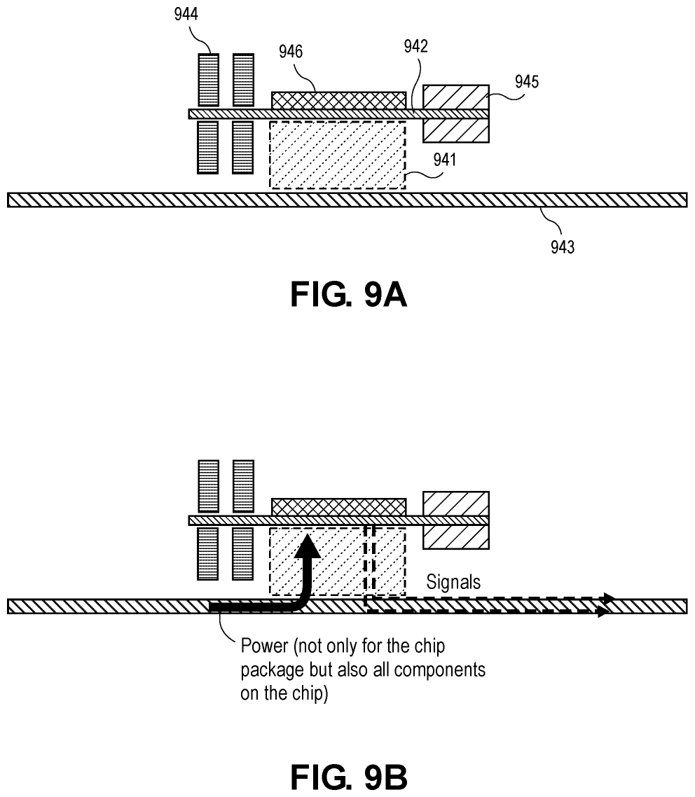

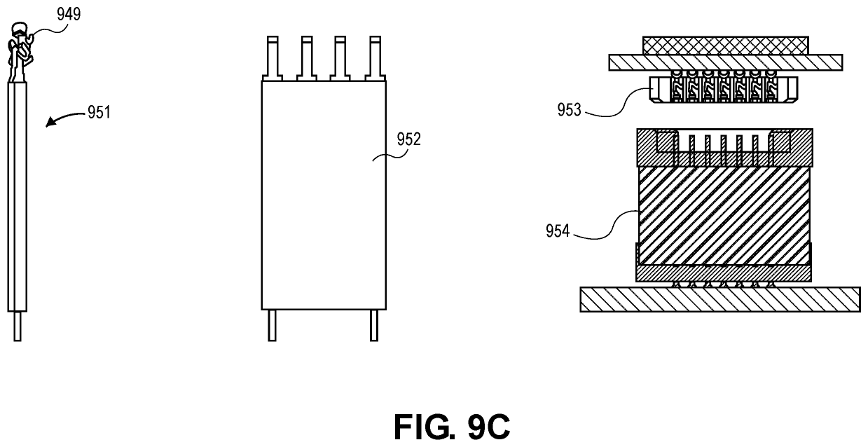

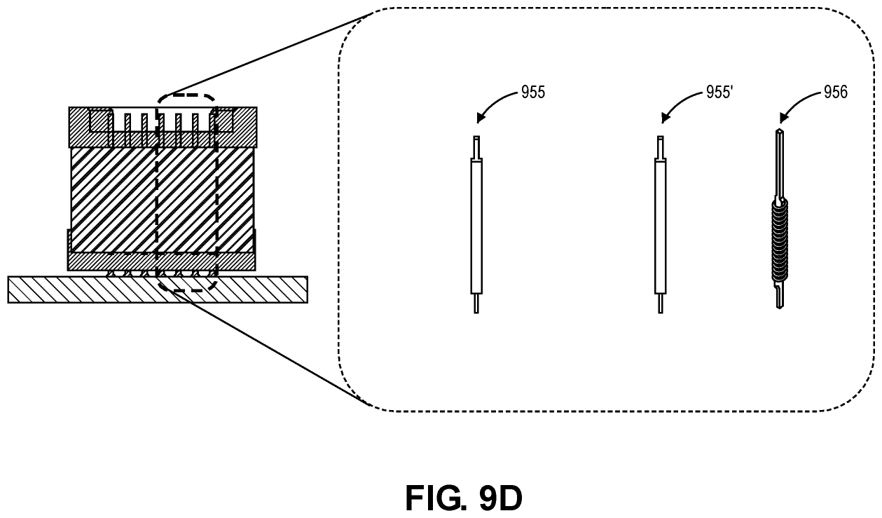

A simplified example of the dual-sided approach is shown in FIG. 9A. As shown, the connector 941 raises a substrate 942 above the baseboard 943. Components (e.g., memory modules 944, network ports 945 (e.g., electrical and/or optical) may be attached to both surfaces of the substrate 942. A chip package 946 is also attached above the connector 941.

The key enabler for this technology is a the connector 941 which provides the following characteristic/performance. The connector 941 is much taller than typical socket e.g., by 8-10×. The connector 941 needs to deliver 3-5× electrical current to power the chip and its satellite components. The connector 941 also carries high speed signals from the chip package through the baseboard to adjacent chip package/module. As shown in FIG. 9B, power and signals are fed through the connector 941. Existing connectors may not meet all of our requirements. One connector may meet the high speed signal integrity, but not at the small pitch that is required, nor can it deliver the high power.

Accordingly, embodiments disclosed herein include two types of contacts. One type of contact is designed for power delivery. The other type of contact is designed for high speed signal. The design scheme for power delivery contacts is shown in FIG. 9C, and the design for high speed signal contacts is shown in FIG. 9D.

The power pins 951 include a dual beam contact 949 (e.g., one or more contact points) in order to provide a low bulk resistance. The male pin portion 951 has a long stubby column using a thick and high conductivity copper alloy. A through-hole pin in lieu of a solder ball is used to enable wave soldering since SMT of tall/bulky connectors is not always feasible. Then, individual male pin portions 951 are grouped together to form a bulk pin 952. This results in a lower total resistance. The short female contacts will be assembled into a thin plastic housing 953. The thin and light body enable SMT to the chip module. The tall pins are assembled into a taller plastic body 954. This piece will be attached to the baseboard using wave-soldering.

As shown in FIG. 9D, the signaling contacts 955 may not be grouped together. In some embodiments that require higher signal speeds, an impedance tuning shield may be added to the signaling contacts 955′, or a pogo contact 956 with shielding may be used.

Increasing data rate requirements and limitations in materials and electrical channel structures, primarily in printed circuit board technologies, are forcing 10 componentry closer to the switch silicon to manage channel loss. One approach is to integrate optical driver componentry as close to the switch as possible. Ideally these could be integrated directly on the switch IC substrate. One disadvantage to this approach is limiting customer configurations that do not require longer connection distances less than 3 m. These shorter connections can be achieved with direct attach copper (DAC) cables. Accordingly, embodiments disclosed herein include architectures that allow for the close coupled approach described above but with configurability for either optical or electrical channel that addresses the limitations of traditional technologies. Embodiments disclosed herein comprise a closely coupled attachment location (on substrate or HDI technology laminate). The attachment location provides a pluggable interface that supports direct co-location with the switch silicon of optical transceivers or electrical channel in the form of a high-speed low loss cable assembly.

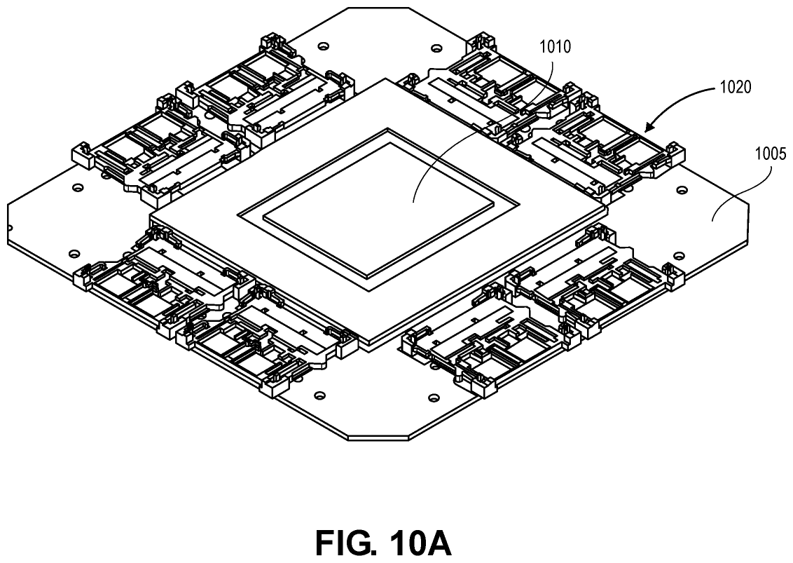

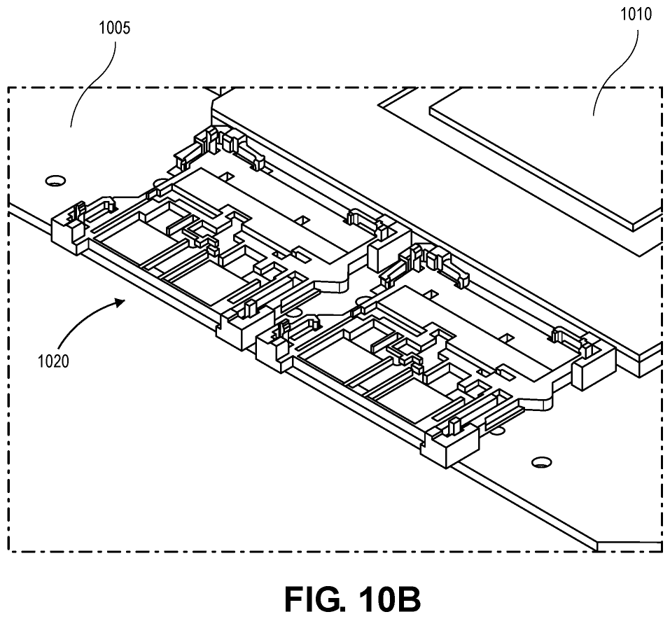

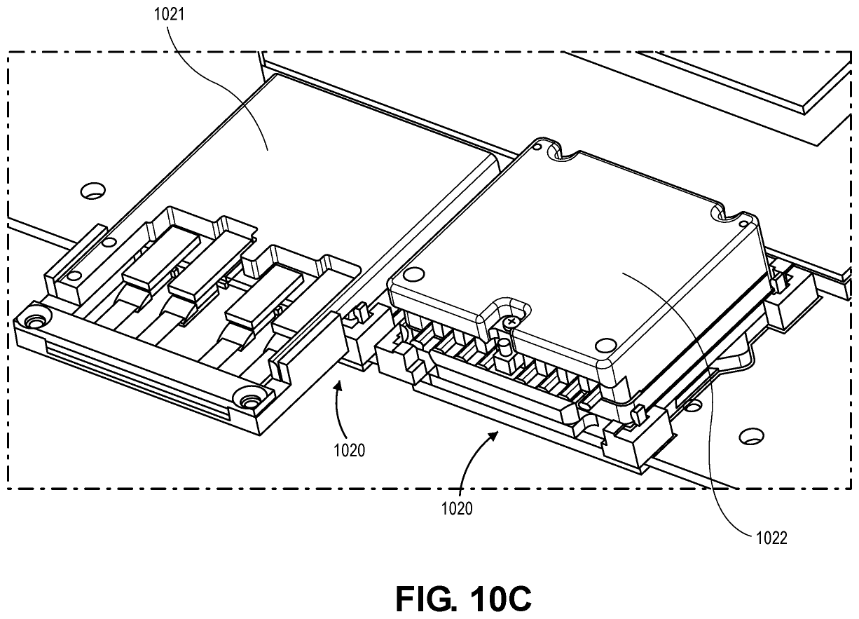

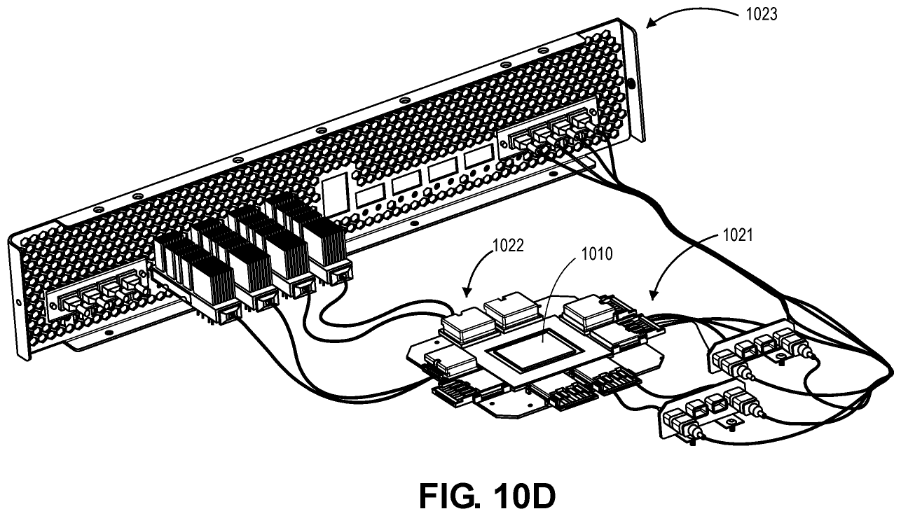

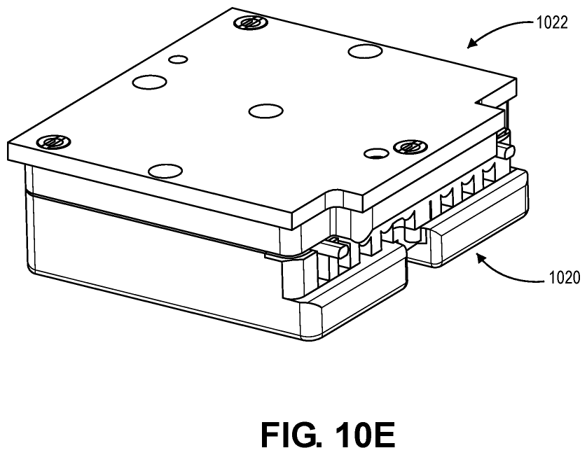

As shown in FIG. 10A, embodiments comprise of a high-speed switch ASIC 1010 applied to an HDI substrate 1005 with high speed/high density sockets 1020. The sockets 1020 may be over both surfaces of the HDI substrate 1005. An optical transceiver or electrical channel cable assembly can be applied to the sockets 1020. Either the transceivers or the electrical channels are cabled to the IO panel/customer interface (not shown). That is, a common interface between the optical component and electrical channel component is provided by the sockets 1020. In this instance a custom optical component is used and a transition HDI laminate is used to adapt a semi-custom high-speed low loss cable assembly. The high-speed socket presents a common interface to the optical transceiver and the electrical channel cable assembly.

A zoomed in illustration of a pair of sockets 1020 are illustrated in FIG. 10B. FIG. 10C illustrates an optical transceiver 1021 attached to a first socket 1020, and an electrical channel device 1022 attached to a second socket 1020. FIG. 10D is a view of the cabling extending out to an interface 1023. As shown, both optical 1021 and electrical 1022 connections are made to a single switch die 1010. FIG. 10E is a perspective view illustration of an electrical channel device 1022 on a socket 1020.

With increased packaging densities and higher power it is becoming increasingly difficult to deliver power into a large-scale IC or multi-chip-module package. The number of high speed IO channels and the associated signal integrity requirements forces these signal pins to the perimeter of the packages. The via patterning in the printed circuit board needed to connect these signals blocks the ability to route power to the central region of the packages where the power connections are located. The traditional solution is to deliver power through a large printed circuit board from around the package but this competes with high speed signaling and componentry needed to support large dynamic currents. Some power management companies are beginning to supply power components that can be applied directly to the back side of the IC package location but this again competes with other required components that are critical for IC operation and are generally not a complete solution.

Accordingly, embodiments disclosed herein apply the power components required for the IC package directly under the package, but on a separate printed circuit board assembly and connected through a high-density connector or a ball/solder column connection. This allows for close coupling of the power delivery for reduced loss and improved dynamics. The interconnect between the mezzanine and IC location can be tailored to allow for decoupling and other high speed components between the mezzanine and the IC location. Also, the design is not locked to a single source and provides a more complete solution.

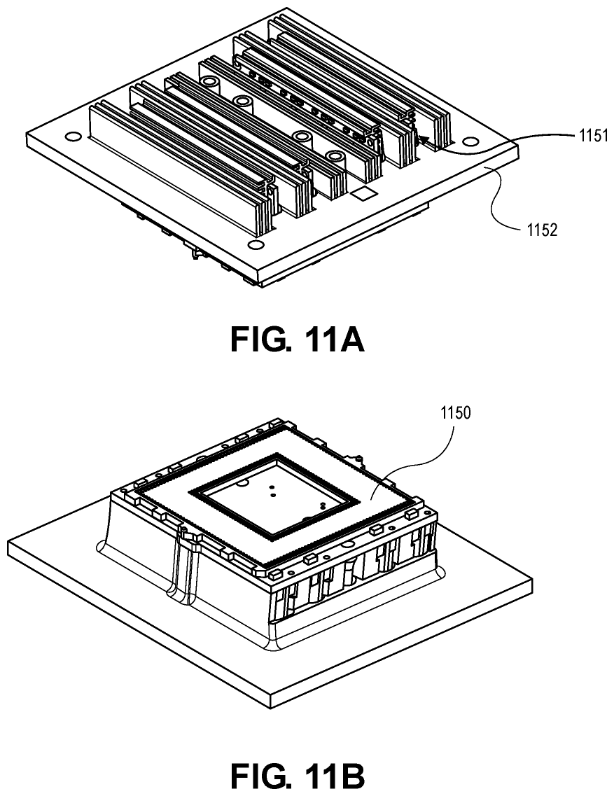

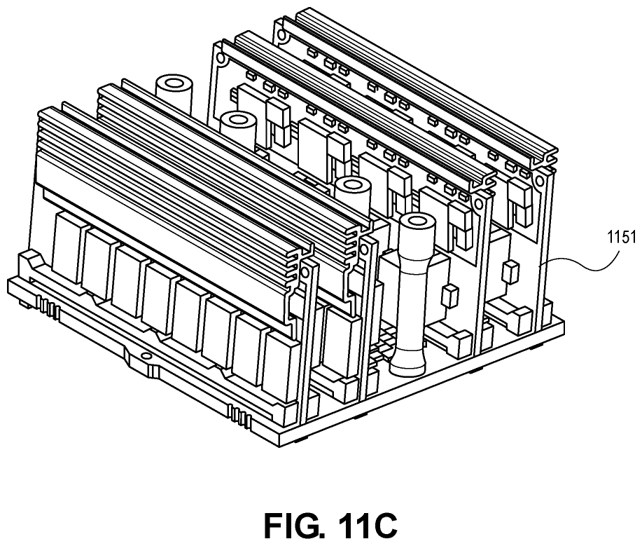

The Example shown in FIGS. 11A-11C provides voltages at high current to the IC site through a Land Grid Array (LGA) connector 1150. This integrates power stages, control functions and thermal management into one assembly. This example utilizes daughter cards 1151 for the power stages providing additional component placement area. Decoupling capacitance is located on the mezzanine. The LGA connector 1150 is pocketed to allow for additional component placement directly on the IC package. A frame 1152 is shown around the daughter cards 1151 in FIG. 11A, and the frame 1152 is removed in FIG. 11C to more clearly see the daughter cards 1151.

Another embodiment disclosed herein is directed to thermal solutions. Increasing performance in high speed switching systems necessitates closer coupling of devices around a centrally located switching IC. The thermal solutions needed to cool these devices generally occupies the volume above the devices. The power dissipation of the switching IC requires a significantly larger projected surface area than the device itself and is generally spread over the other devices creating a layered effect. In some cases, the other devices are active and need a thermal solution also. This increases the height of the layered effect. Traditionally this height is achieved by adding a pedestal in the base of the heatsink allowing the heat to be conducted through the base to the fin surface. With increasing power densities, the conduction path through the pedestal material becomes unmanageable in the thermal solution. The addition of material in the base has been used to increase the height of the heatsink base to clear other components adjacent to the switching IC, but the conduction lost can become unmanageable with higher power densities. Some designs utilize heatpipes or flat vapor chambers to reduce conduction loss. Heatpipes are limited by fabrication constraints/bend radii and vapor chambers are generally planar.

Accordingly, embodiments disclosed herein comprise vapor chamber technology with an elevated fin stack. Instead of adding a solid copper pedestal to the base to elevate the fin stack to clear adjacent componentry, the base shell of the vapor chamber includes a formed or machined section as the pedestal shape such that the evaporator surface that is in contact with the IC switch is much thinner than with a solid pedestal. This limits the conduction loss. The wick structure internal to the vapor chamber follows the wall of the pedestal from the large base of the heatsink to the evaporator surface. This takes advantage of the vapor chamber benefits with the extended height required for these higher density/high power applications.

Embodiments may include an evaporator site, a condenser site and a wick structure. The wick structure is required to control evaporation at the heat input site and to return liquid from the condensation surface back to the evaporator site. In an embodiment, the base shell of the vapor chamber has a region that is formed or machined into the pedestal shape such that the evaporator surface in contact with the IC switch is much thinner than if a solid pedestal was used. This limits the conduction loss. The height of the pedestal has limited performance impact and can be adjusted to meet the requirements of the overall system design. The wick structure follows the wall of the pedestal from the large base of the heatsink to the evaporator surface. This provides a continuous path for the liquid to return to the evaporator site.

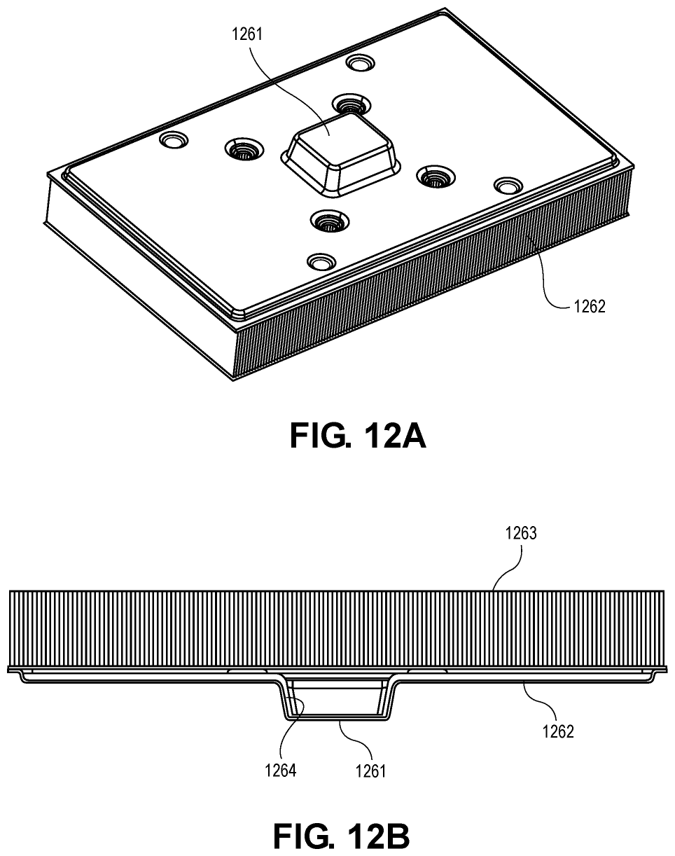

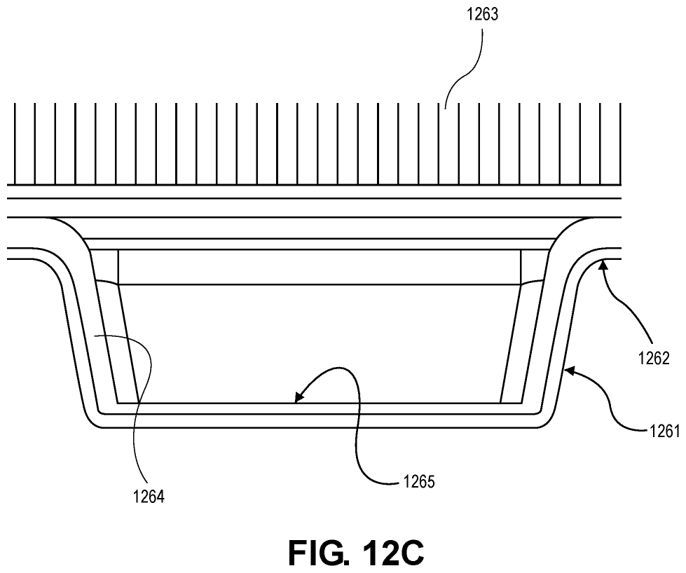

An example of such an embodiment is shown in FIGS. 12A-12C. FIG. 12A illustrates a pedestal 1261 that extends up from a base 1262. As shown in the cross-section in FIG. 12B, the base is attached to a fin stack 1263. The interior of the pedestal 1261 and the base 1262 is lined with a wick structure 1264. These features are shown more clearly in FIG. 12C. As shown, the evaporator surface 1265 (which is thermally coupled to the IC—not shown) is thin. This limits conduction loss.

In high density packaging solutions coupling several MCM (multi-chip-modules) packages together requires mechanically independent thermal sites for each MCM location to be able to accommodate mechanical tolerances between sites while providing a single fin stack for improved air flow and thermal dissipation. Independent heatpipe, heatsinks, or a single heatsink have been used in previous designs. In integrating multiple closely coupled MCMs with increasing power densities it becomes difficult to implement independent fin stacks. The alignment and starts and stops between independent fin stacks reduce the amount of fin area and increases the pressure drop in the fin area which reduces flow rates. Single heatsinks covering multiple sites can cause mechanical stress and increase thermal loss due to misalignment.

Accordingly, embodiments, include a heatpipe heatsink with multiple evaporator locations all connected to a single fin stack via tubular heatpipes. The compliancy of the heatpipes allows for relative motion between evaporator sites to accommodate dimensional differences in the devices being cooled. This provides a lower pressure drop reducing fan speed and noise. Single heatsinks to cool multiple sites also reduces costs. Additionally, the ability of sites to operate at significantly different power levels improves functionality.

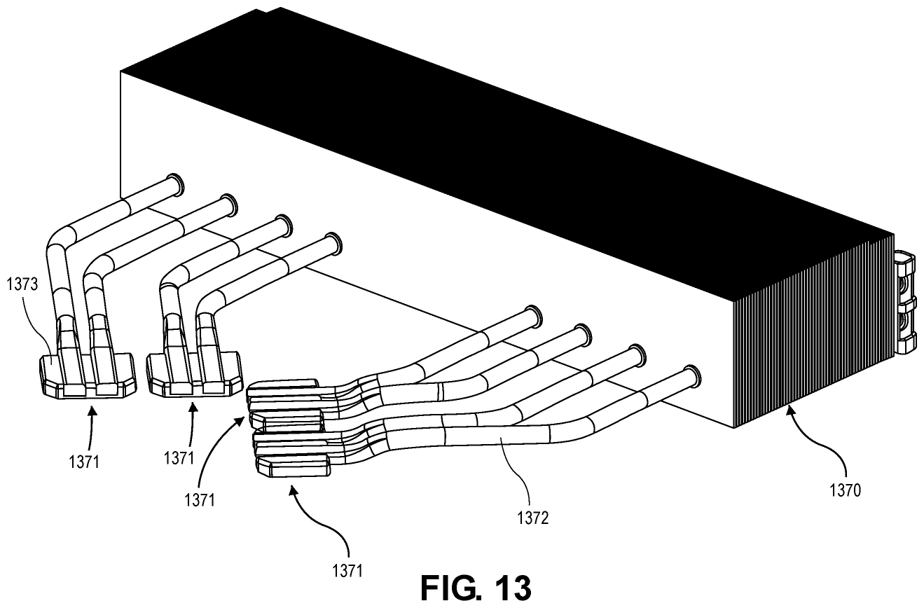

FIG. 13 is an example of such an embodiment. As shown, a single heatpipe heatsink 1370 couples multiple heat source locations 1371 to single fin stack through multiple heatpipes 1372. Each site requires at least one heatpipe 1372. Multiple heatpipes 1372 per site can be used to increase power capability. The metal slug 1373 at the heat source 1371 is the evaporator of the heatpipe 1372. The fin stack 1370 is the condenser side of the heatpipe 1372. The single fin stack 1370 offers lower pressure drop and increased surface area over individual fin stacks for each heat source. The multi-site concept also accommodates different height heat sources. Compliancy in the heatpipes 1372 provides for relative motion between the various evaporator sites 1373 to accommodate tolerances and variations in the assembly.

In an embodiment, the heatsink has independent evaporator sites. In an embodiment, the heatsink has an extended evaporator chamber. In an embodiment, the heatsink retention mechanism supports independent heat pipe sites. In an embodiment, independent thermal solutions for the switch and for the photonic engines are provided. Such cooling may be liquid cooling as well as the described air-cooling concepts. Embodiments support either with or without heat pipes and with or without discrete thermal solutions for both the switch and the photonic engines. Embodiments support flow of liquid from outside of the integrated package, either within the switch box, the switch chassis, or supported outside the switch chassis.

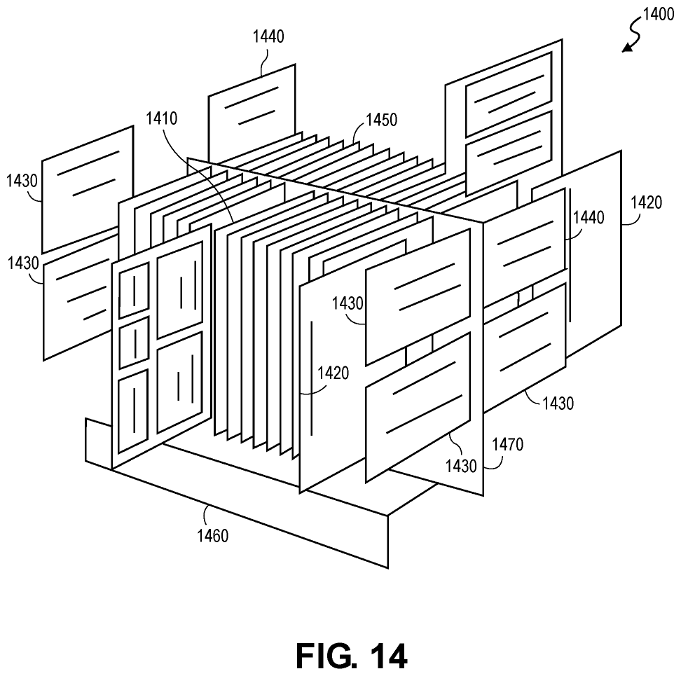

FIG. 14 illustrates a modular server system according to an embodiment of the present invention. In an embodiment, the modular server system 1400 is a redundant server system for Web hosting and ASPs requiring server solutions with carrier-class availability, reliability, and scalability. Carrier-class systems have features that are more demanding than enterprise-grade systems, such as “high availability” (HA), high dependability and redundancy. However, it is to be appreciated that embodiments described herein are also applicable to enterprise-grade server systems. In other embodiments, the modular server system 1400 may be used for any computing system. For example, the modular server system 1400 may be part of a high performance computing systems. The modular server system 1400 may also be a disaggregated computing network.

At the heart of the modular server system 1400 is the mid plane 1470, which may be a PC-style circuit board having a plurality of blade interfaces providing a common interconnect for all modules connected thereto. The blade interfaces are in electrical communication with each other and with the system management bus of the midplane 1470. The midplane 1470 is preferably based on a CompactPCI form factor (CompactPCI Specification, PICMG 2.0, Version 2.1, by the PCI (Peripheral Component Interconnect) Industrial Computer Manufactures Group (PICMG)), wherein the blade interfaces are CompactPCI slots or connectors. CompactPCI utilizes the Euro card form factor popularized by the “Versa Module Europa” (VME) bus having standard Eurocard dimensions and high density 2 mm pin-and-socket connectors. In the modular server system 1400 illustrated in FIG. 14, up to sixteen independent server blades 1410 may be supported, along with up to sixteen media blades 1450. However, any other numbers of server blades 1410 and media blades 1450 may be supported. A blade is generally a mother board or a single board computer (SBC) having a central processing unit (CPU). Although it is preferable that each server blade 1410 have a corresponding media blade 1420, it is not a requirement, as multiple server blades 1410 may share a single media blade 1420, and vice versa. By utilizing the midplane 1470, the network (such as the local area network) becomes the primary interconnect between the blades 1410, 1450.

The modular server system 1400 illustrated in FIG. 14 is also adapted to support any number of switch blades 1420 for complete system network (e.g., Ethernet) switching and N+1 redundancy. The switch blades 1420 may be optical switch blades for switching optical signals within the modular server system 1400 or between different modular server systems (e.g., different racks). In an embodiment, the switch blades 1420 may comprise electronic packages, such as those described above that include a plurality of photonic engines positioned on both surfaces of an interposer. The photonic engines may be communicatively coupled to a switch die that is connected to the interposer through a second package substrate. In an embodiment, the electronic package comprising the photonic engines and the switch die are coupled to a board by sockets with a stand-off height of approximately 15 mm or greater, approximately 20 mm or greater, or approximately 25 mm or greater. In an embodiment, the board connects to the midplane 1470 using an interface, such as those described above.

In an embodiment, the switch blades 1420 have twenty 10/100 Base-T auto-negotiating ports and support 4,096 Media Access Controller (MAC) addresses. Preferably, of the twenty ports, sixteen of them are assigned to one Ethernet channel from the system's 1400 mid plane 1470 (connected to all sixteen server blades 1410, as illustrated in the example in FIG. 14), and the remaining four ports are accessible through RJ-45 (Ethernet) connectors, for example, on the switch blade's 1420 face plate. However, other configurations may be adapted depending on the number of server blades 1410 supported by the modular server system 1400 and depending on whether optical routing is used instead of electrical routing. Data packets are preferably buffered in the switch blade 1420 so that Ethernet collisions do not occur on any channel, and a full-managed Layer 3/4 switch may provide Quality of Service (QoS) control, while in all cases a non-block switch fabric with sufficient bandwidth to prevent packet loss is recommended.

In the modular server system 1400 illustrated in FIG. 14, a plurality of load sharing power supplies 1430 may be connected to the midplane 1470 to provide power to the modules of the server system 1400. These power supplies 1430 (e.g., 150 W power supplies) may provide for N+1 redundancy as well. One or more (AC/ DC) inputs 1440 may be connected to the midplane 1470 to provide input power to the modular server system 1400. A removable fan tray with cooling fans 1460 may be utilized to provide cooling air flow within the modular server system 1400 to cool the modules therein. In other embodiments, a liquid cooling system can be used instead of (or in addition to) the cooling fans 1460. The power supplies 1430 and the cooling fans 1460 of the modular server system 1400 may be shared by the server blades 1410, the media blades 1450, and the switch blades 1420 within the modular server system 1400 (i.e., each server blade 1410, media blade 1450, or switch blade 1420 need not have its own power supply or cooling fan). The sharing of the power supplies 1430 and cooling fans 1460 provides a more efficient use of the resources of the modular server system 1400 and minimizes space.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a first package substrate; a second package substrate attached to the first package substrate; a die attached to the second package substrate; and a plurality of photonic engines attached to a first surface and a second surface of the first package substrate, wherein the plurality of photonic engines are communicatively coupled to the die through the first package substrate and the second package substrate.

Example 2: the electronic package of Example 1, wherein the plurality of photonic engines surround a perimeter of the die.

Example 3: the electronic package of Example 1 or Example 2, wherein the die comprises four edges, and wherein four photonic engines are adjacent to each of the four edges.

Example 4: the electronic package of Example 3, wherein a first two of the four photonic engines are on the first surface of the first package substrate, and wherein a second two of the four photonic engines are on the second surface of the first package substrate.

Example 5: the electronic package of Examples 1-4, wherein photonic engines on the first surface of the first package substrate are each directly above photonic engines on the second surface of the first package substrate.

Example 6: the electronic package of Examples 1-5, wherein the photonic engines convert optical signals to electrical signals and/or convert electrical signals to optical signals.

Example 7: the electronic package of Examples 1-6, wherein the die is a switch die.

Example 8: the electronic package of Example 7, wherein the electronic package is a top of the rack switch.

Example 9: the electronic package of Examples 1-8, wherein the photonic engines are attached to the first package substrate by sockets.

Example 10: the electronic package of Examples 1-9, further comprising: a socket attached to the first surface of the first package substrate.

Example 11: the electronic package of Example 10, wherein the socket has a standoff height that is greater than a thickness of the photonic engines.

Example 12: the electronic package of Example 11, wherein the standoff height of the socket is approximately 15 mm or greater.

Example 13: the electronic package of Examples 10-12, wherein the socket is within a footprint of the die.

Example 14: the electronic package of Examples 1-13, further comprising: a thermal solution coupled to each of the photonic engines.

Example 15: an electronic package, comprising: a package substrate with a first surface and a second surface; a switch die coupled to the second surface of the package substrate; and a plurality of photonic engines coupled to the first surface and the second surface of the package substrate, wherein the plurality of photonic engines are communicatively coupled to the switch die through the package substrate.

Example 16: the electronic package of Example 15, wherein the plurality of photonic engines comprises a first set of photonic engines on the first surface of the package substrate and a second set of photonic engines on the second surface of the package substrate, wherein each of the photonic engines in the first set of photonic engines is directly below different ones of the photonic engines in the second set of photonic engines.

Example 17: the electronic package of Example 15 or Example 16, wherein the plurality of photonic engines comprises eight or more photonic engines.

Example 18: the electronic package of Examples 15-17, wherein the switch die is coupled directly to the package substrate by an interconnect.

Example 19: the electronic package of Examples 15-18, wherein the switch die is on a second package substrate, and the second package substrate is coupled to the second surface of the package substrate by an interconnect.

Example 20: the electronic package of Examples 15-19, further comprising: a socket coupled to the first surface of the package substrate, wherein the socket is directly below the switch die.

Example 21: the electronic package of Examples 15-20, wherein the electronic package is a top of the rack switch.

Example 22: an electronic system, comprising: a board; a package substrate with a first surface and a second surface, wherein the first surface is coupled to the board by a socket; a switch die coupled to the second surface of the package substrate or an interposer; and a plurality of photonic engines coupled to the first surface and the second surface of the package substrate, wherein a standoff height of the socket is greater than a thickness of the photonic engines.

Example 23: the electronic system of Example 22, wherein the socket is configured to provide power delivery and RF signal delivery.

Example 24: the electronic system of Example 22 or Example 23, wherein the socket comprises copper blades.

Example 25: the electronic system of Examples 22-24, wherein the socket is configured to connect to a daughter card.

What is claimed is:

1. An electronic package, comprising:
a first package substrate;
a second package substrate attached to the first package substrate;
a die attached to the second package substrate; and
a plurality of photonic engines attached to a first surface and a second surface of the first package substrate, wherein the plurality of photonic engines are communicatively coupled to the die through the first package substrate and the second package substrate.

2. The electronic package of claim 1, wherein the plurality of photonic engines surround a perimeter of the die.

3. The electronic package of claim 1, wherein the die comprises four edges, and wherein four photonic engines are adjacent to each of the four edges.

4. The electronic package of claim 3, wherein a first two of the four photonic engines are on the first surface of the first package substrate, and wherein a second two of the four photonic engines are on the second surface of the first package substrate.

5. The electronic package of claim 1, wherein photonic engines on the first surface of the first package substrate are each directly above photonic engines on the second surface of the first package substrate.

6. The electronic package of claim 1, wherein the photonic engines convert optical signals to electrical signals and/or convert electrical signals to optical signals.

7. The electronic package of claim 1, wherein the die is a switch die.

8. The electronic package of claim 7, wherein the electronic package is a top of the rack switch.

9. The electronic package of claim 1, wherein the photonic engines are attached to the first package substrate by sockets.

10. The electronic package of claim 1, further comprising:
a socket attached to the first surface of the first package substrate.

11. The electronic package of claim 10, wherein the socket has a standoff height that is greater than a thickness of the photonic engines.

12. The electronic package of claim 11, wherein the standoff height of the socket is approximately 15 mm or greater.

13. The electronic package of claim 10, wherein the socket is within a footprint of the die.

14. The electronic package of claim 1, further comprising:
a thermal solution coupled to each of the photonic engines.

15. An electronic package, comprising:
a package substrate with a first surface and a second surface;
a switch die coupled to the second surface of the package substrate; and
a plurality of photonic engines coupled to the first surface and the second surface of the package substrate, wherein the plurality of photonic engines are communicatively coupled to the switch die through the package substrate.

16. The electronic package of claim 15, wherein the plurality of photonic engines comprises a first set of photonic engines on the first surface of the package substrate and a second set of photonic engines on the second surface of the package substrate, wherein each of the photonic engines in the first set of photonic engines is directly below different ones of the photonic engines in the second set of photonic engines.

17. The electronic package of claim 15, wherein the plurality of photonic engines comprises eight or more photonic engines.

18. The electronic package of claim 15, wherein the switch die is coupled directly to the package substrate by an interconnect.

19. The electronic package of claim 15, wherein the switch die is on a second package substrate, and the second package substrate is coupled to the second surface of the package substrate by an interconnect.

20. The electronic package of claim 15, further comprising:
a socket coupled to the first surface of the package substrate, wherein the socket is directly below the switch die.

21. The electronic package of claim 15, wherein the electronic package is a top of the rack switch.

22. An electronic system, comprising:
a board;
a package substrate with a first surface and a second surface, wherein the first surface is coupled to the board by a socket;
a switch die coupled to the second surface of the package substrate or an interposer; and
a plurality of photonic engines coupled to the first surface and the second surface of the package substrate, wherein a standoff height of the socket is greater than a thickness of the photonic engines.

23. The electronic system of claim 22, wherein the socket is configured to provide power delivery and RF signal delivery.

24. The electronic system of claim 23, wherein the socket comprises copper blades.

25. The electronic system of claim 23, wherein the socket is configured to connect to a daughter card.
